(19) United States
(12) Patent Application Publication
(10) Pub. No.: US 2026/0324152 A1
(43) Pub. Date: Oct. 15, 2026

(54) OPTOELECTRONIC DEVICE AND SYSTEM FOR OPTICAL DATA COMMUNICATION

(71) Applicant: ams-OSRAM International GmbH, Regensburg (DE)

(72) Inventors: Tansen Varghese, Regensburg (DE); Philipp Kreuter, Regensburg (DE); Martin Hetzl, Painten (DE); Norwin von Malm, Thumhausen/Nittendorf (DE)

(21) Appl. No.: 19/483,949

(22) PCT Filed: May 16, 2024
(86) PCT No.: PCT/EP2024/063458

§ 371 Date: Nov. 12, 2025

(30) Foreign Application Priority Data
May 16, 2023 (DE) 10 2023 112 946.5

(51) Int. Cl. H10H 20/856; H10F 39/90; H10H 29/20

(52) U.S. Cl. CPC H10H 20/856; H10F 39/90; H10H 29/20

(57) ABSTRACT

In an embodiment a system for optical data communication includes a first arrangement of optoelectronic devices and a second arrangement of optoelectronic devices, wherein the optoelectronic devices of the first arrangement are optically coupled with a respective optoelectronic device of the second arrangement, and wherein the optoelectronic devices of at least one of the first arrangement or the second arrangement comprise a first semiconductor layer stack comprising a first layer, a second layer and a first active region between the first and second layers, wherein the first and second layers are of different conductivity types, and a second semiconductor layer stack arranged on the first semiconductor layer stack comprising a third layer, a fourth layer and a second active region between the third and fourth layers, wherein the third and fourth layers are of different conductivity types, and an optical layer between the first semiconductor layer stack and the second semiconductor layer stack.

### CROSS-REFERENCE TO RELATED APPLICATIONS

This patent application is a national phase filing under section 371 of PCT/EP2024/063458, filed May 16, 2024, which claims the priority of German patent application no. 10 2023 112 946.5, filed May 16, 2023, each of which is incorporated herein by reference in its entirety.

### TECHNICAL FIELD

The present invention concerns an optoelectronic device, an arrangement of optoelectronic device and a system for optical data communication. The present invention further concerns a method for operating an optoelectronic device and for operating a system for optical data communication.

### BACKGROUND

Today's Internet relies on large data centres. However, their high-power consumption poses problems to ensure their operation with purely sustainable energy sources. Most of the power is consumed not for computations, but for data transmission over short distances (<<10 m) : CPU to memory, server to server, rack to rack.

Currently, short-range data communication is either done electrically, mainly by copper (Cu) or aluminium (Al) feed lines and wires (intra-chip or within mainboard), or optically by the combination of near infrared (NIR) vertical-cavity surface-emitting lasers (VCSEL) with optical fibres. The metals however cause electrical power losses due to their specific resistance and the VCSELs on the other hand have noise issues due to the coherent emission.

To reduce the power for optical short range data transmission there are activities on using μ-LEDs to tackle the challenge of high power consumption. μ-LEDs namely have the advantage of a possible operation with low currents (>0.1 μA per pixel), which is many factors lower as for lasers, e.g. VCSELs, and they don't have coherent emission. In addition, μ-LEDs have a small footprint (<5 μm possible) and can be transferred to backplane wafers by common display technologies, thus a high parallelization while transferring the μ-LEDs can be achieved further reducing the power consumption while manufacturing the hardware.

The use of small optoelectronic components such as μ-LEDs for optical data communication has thus major benefits to, e.g., VCSEL technology.

The use of small optoelectronic components such as μ-LEDs however requires, besides a high quantum efficiency, a very fast “switchability” of the emitters in order to allow for high data rates. One limitation with respect to this is radiative recombination lifetime, limiting the rise and fall time of light emission when modulating or turning on/off the μ-LED.

Currently known approaches to decrease radiative recombination lifetime include for example background doping (e.g. in the active region) in order to increase charge carrier density for certain charge carrier types, the use of Quantum dots, and/or to try and achieve a high current density.

These methods can however only improve the performance of the optoelectronic components to a certain extent.

### SUMMARY

Embodiments provide an optoelectronic component as well as a system for optical data communication that counteracts at least some of the disadvantages mentioned.

Embodiments provide an optoelectronic component as well as a system using such optoelectronic components by means of which wavelength division multiplexing (WDM) is possible to increase the transmittable data rate via a single optical fibre. This can be done with multijunction (multiwavelength) multiterminal μ-LEDs and/or μ-detectors. These can be stacked (grown or bonded with TCO on top of each other) semiconductor layer stacks with each stack having an active region/junction and a pair of terminals to control each active region/junction. The stacked semiconductor layer stacks each comprise an active region with a different bandgap, thus configured to emit/detect light of different wavelengths. The stacked semiconductor layer stacks are further divided by an optical layer configured to let light emitted/to be detected by the lower semiconductor layer stack pass, whereas light emitted/to be detected by the upper semiconductor layer stack is blocked/reflected by the optical layer. Each junction in each semiconductor layer stack is individually addressable, to allow an independent operation of the layer stacks as independent emitters emitting light of different wavelengths or to independently detect incident light of the different wavelengths. This way in a system for optical data communication each core of a multicore fibre coupled with such a stacked emitter/detector can transmit simultaneous signals in more than one wavelength to increase the bandwidth of the data communication.

In a first embodiment, an optoelectronic device, in particular μ-LED and/or μ-Detector, is provided. The optoelectronic device comprises at least a first semiconductor layer stack and a second semiconductor layer stack arranged on the first semiconductor layer stack. The first semiconductor layer stack comprises a first layer, a second layer and a first active region between the first and the second layer, wherein the first and the second layer are of different conductivity types. The second semiconductor layer stack comprises a third layer, a fourth layer and a second active region between the third and the fourth layer, wherein the third and the fourth layer are of different conductivity types. In particular the first layer and the third or the fourth layer can be of the same conductivity type while the second layer can be of the same conductivity type as the conductivity type of the other of the one of the third or the fourth layer. For example, the first layer can comprise an n-doping and the second layer can comprise a p-doping, but the ordering can also be the other way around.

To be able to emit or detect light of different wavelengths, the first active region comprises a smaller bandgap than the second active region. In addition, an optical layer is arranged between the first semiconductor layer stack and the second semiconductor layer stack, which comprises a higher transparency for light with energy smaller than the second bandgap, and in particular larger to or equal to the first bandgap, than for light with energy equal to or greater than the second bandgap. By this it can be provided that light emitted by means of the first semiconductor layer stack or that is to be detected by means of the first semiconductor layer stack can transmit through the optical layer whereas light emitted by means of the second semiconductor layer stack or that is to be detected by means of the second semiconductor layer stack is not able to transmit through the optical layer and thus prevents a disturbance of the respective other semiconductor layer stack and also increases the efficiency of the two stacked active regions.

The optoelectronic device further comprises a bottom contact element electrically contacting the first layer, a middle contact element being in electric contact with the second layer and the third layer and a substantially transparent top contact element electrically contacting the fourth layer. By means of this contact elements the first and the second semiconductor layer stack can be individually operable while being in electric contact to one common potential.

It is to be understood that more than the indicated two semiconductor layer stacks can in such a way be stacked on top of each other with an optical layer in between. The active regions of the semiconductor layer stacks would in a case of more than two layer stacks comprise the smallest bandgap within the active region of the lowest semiconductor layer stack and the largest bandgap within the active region of the uppermost semiconductor layer stack with the active regions in between the lowest and the uppermost semiconductor layer stack comprising increasing bandgaps from the lowest to the uppermost semiconductor layer stack. The optical layers inbetween are on the other hand configured to let light emitted/to be detected by the respective lower semiconductor layer stack(s) pass, whereas light emitted/to be detected by the respective upper semiconductor layer stack(s) is reflected by the optical layer. By this an optoelectronic device can be configured to emit/detect even more than two different wavelengths at a time.

In some embodiments, the optoelectronic device is a μ-LED and/or μ-Detector. A μ-LED/μ-Detector can in particular be a device with edge lengths smaller than 100 μm, smaller than 50 μm, smaller than 20 μm, smaller than 10 μm or smaller than 5 μm being configured to emit and/or detect light of a desired wavelength.

In some embodiments, the optical layer is a distributed Bragg reflector (DBR). For example, semiconductor material (epi) between the first and the second semiconductor layer stack can contain a DBR to reflect shorter wavelength light and to transmit the longer wavelength light of or to the first semiconductor layer stack. The DBR can in particular be monolithically integrated with the first and second semiconductor layer stacks. However, the optical layer can be of either of the two material systems or of another material system. In this case the optical layer can be monolithically integrated with the first or second semiconductor layer stacks or can be attached to the first and/or second semiconductor layer in any other way.

In some embodiments, the middle contact element comprises the optical layer. The semiconductor material (epi) between the first and the second semiconductor layer stack can comprise substantially transparent current spreader and contact layers for the common contact to both semiconductor layer stack. This current spreader and contact layers can be combined with the optical layer for example in form of a DBR or a multilayer spreader.

In some embodiments, the optoelectronic device comprises a light emitting area/light incident area above the top contact element opposite the semiconductor layer stacks. Through this light emitting area light generated within the layer stacks can be outcoupled from the optoelectronic device, or through this light incident area, light can be incoupled into the optoelectronic device to be detected by the semiconductor layer stacks. The light emitting area/light incident area can be formed by either the top contact element itself or further structure(s) element(s) as described later herein.

In some embodiments, the bottom contact element comprises a reflective material layer covering the first layer opposite the first active region. This allows a directional radiation of generated light in the direction of the top contact element and more efficient outcoupling of the generated light through the light emitting area. On the other hand, the detection efficiency of the optoelectronic device can be increased, as not yet detected but through the semiconductor layer stacks propagated light is reflected within the optoelectronic device to be possibly detected “at a further attempt” when propagating back again through the semiconductor layer stacks.

In some embodiments, the optical layer not only comprises a different transparency for the light of different wavelengths but also comprises a higher absorption and/or reflection for light with energy equal to or greater than the second bandgap than for light with energy lower than the second bandgap. Thus, the absorption and/or reflection of the optical layer is higher for light with the second wavelength than for light with the first wavelength. This for example allows a redirection of light generated in the second semiconductor layer stack in the direction of the top contact element and a more efficient outcoupling of the generated light through the light emitting area. On the other hand, the detection efficiency of the optoelectronic device can be increased, as not yet detected but through the second semiconductor layer stack propagated light of the second wavelength is reflected by the optical layer to be possibly detected “at a further attempt” when propagating back again through the second semiconductor layer stack.

In some embodiments, the first semiconductor layer stack is configured to be able to emit and detect light of a first wavelength and the second semiconductor layer stack is configured to able to emit and detect light of a second wavelength, wherein the first wavelength is larger than the second wavelength.

In some other embodiments, the first semiconductor layer stack is configured to emit light of a first wavelength and the second semiconductor layer stack is configured to emit light of a second wavelength, wherein the first wavelength is larger than the second wavelength.

In some other embodiments, the first semiconductor layer stack is configured to detect light of a first wavelength and the second semiconductor layer stack is configured to detect light of a second wavelength, and wherein the first wavelength is larger than the second wavelength.

In case of the optoelectronic device and in particular the first semiconductor layer stack and the second semiconductor layer stack are primarily configured to emit light, the structure of the optoelectronic device and in particular the first semiconductor layer stack and the second semiconductor layer stack can be in general the same as for an optoelectronic device being configured to primary detect light, however the semiconductor layer stacks can be differently optimized. This may differ in thicknesses (for example QWs or heterostructures), doping profiles and different compositions within each material system.

The semiconductor layer stacks can be of different shapes, for example a truncated pyramidal shape with angled side surfaces or a truncated conical shape with angled side surfaces. Such angled side surfaces can for example result from a mesa etching process. The semiconductor layer stacks of one optoelectronic device can be of the same size or can vary between the semiconductor layer stacks. For example, the semiconductor layer stacks are arranged in steps with the second semiconductor layer stack having a larger cross section as the first semiconductor layer stack. These exemplary embodiments are however not to be understood in a limiting way but just as possible embodiments. Many other arrangements, shapes and cross sections are possible.

In some embodiments, the middle contact element comprises a reflective coating extending alongside surfaces of the first semiconductor layer stack and the second semiconductor layer stack. This for example allows a directional radiation of light generated in the semiconductor layer stacks in the direction of the top contact element and a more efficient outcoupling of the generated light through the light emitting area. On the other hand, the detection efficiency of the optoelectronic device can be increased, as not yet detected but through the semiconductor layer stacks propagated light is reflected within the semiconductor layer stacks to be possibly detected “at a further attempt” when propagating back again through the semiconductor layer stacks.

In some embodiments, a dielectric layer is arranged between the side surfaces of the first semiconductor layer stack and the second semiconductor layer stack and the reflective coating. In this way, a short circuit within the optoelectronic device that could be caused by the reflective coating when it electrically connects the first, middle, and top contact element can be prevented.

In some embodiments, the optoelectronic device further comprises an outcoupling/incoupling structure on the top contact element opposite the fourth layer. The outcoupling/incoupling structure for example forms the light emitting area/light incident area. The outcoupling/incoupling structure can for example be a surface roughening of the top contact element or of a further layer arranged on the top contact element. In this way an out- and/or incoupling of light from and into the optoelectronic device can be improved, as well as a directionality of the outcoupled light can be improved. In addition, an incoupling of light into an adjacent optical fibre can by this be improved.

In some embodiments, the optoelectronic device further comprises an optical element on the top contact element opposite the fourth layer or on the outcoupling/incoupling structure. The optical element can for example be a μ-lens or a photonic structure. In this way an out- and/or incoupling of light from and into the optoelectronic device can be improved, as well as a directionality of the outcoupled light can be improved. In addition, an incoupling of light into an adjacent optical fibre can by this be improved.

In some embodiments, the optoelectronic device further comprises a carrier substrate, wherein the carrier substrate comprises a supply circuit electrically connected to the bottom, middle and top contact element. The carrier substrate can for example be in form of a CMOS element or a portion of a CMOS wafer.

In some embodiments, the carrier substrate is bonded to extensions of the bottom, middle and top contact element, or directly bonded to at least the bottom contact element and in particular bonded to the middle and top contact element. The carrier substrate can however also be monolithically integrated with the semiconductor layer stacks and the contact elements. It is also conceivable that the optoelectronic device comprises no carrier substrate and is at a later stage placed on a respective carrier substrate.

In some embodiments, optoelectronic device(s) according to the proposed principle can be processed as individual elements, capable of being for example transfer printed or transferred onto a carrier substrate. In some embodiments, optoelectronic devices according to the proposed principle can however also be processed as an array/a plurality of optoelectronic devices arranged adjacent on a carrier substrate forming an arrangement.

In a further embodiment, it is thus provided an arrangement comprising a carrier substrate and a plurality of optoelectronic devices according to some embodiments of the proposed principle arranged adjacent to each other on the carrier substrate. In some embodiments, the optoelectronic devices are thereby arranged in an array in rows and columns and for example connected with a filler material, for example a polymer filler material.

In a further embodiment, it is provided a system for optical data communication comprising a first arrangement of optoelectronic devices and a second arrangement of optoelectronic devices, wherein at least one of the first and second arrangement are an arrangement according to some embodiments of the proposed principle. The optoelectronic devices of the first arrangement are thereby optically coupled with a respective optoelectronic device of the second arrangement to transmit optical data between a respective emitter and detector.

In some embodiments, the optoelectronic devices of the first arrangement are configured to emit light of a first and a second wavelength and wherein the optoelectronic devices of the second arrangement are configured to detect the light of the first and second wavelength emitted by the respective optoelectronic device of the first arrangement. Thus, the first arrangement is configured to emit optical data and the second arrangement is configured to detect optical data. For on optical data communication one would need on each side of the communicating objects an arrangement configured to emit optical data and an arrangement configured to detect optical data.

In some embodiments, the optoelectronic devices of the first arrangement are configured to emit at a first point of time light of a first and a second wavelength, wherein the optoelectronic devices of the second arrangement are configured to detect the light of the first and second wavelength emitted by the respective optoelectronic device of the first arrangement at the first point of time, wherein the optoelectronic devices of the second arrangement are configured to emit at a second point of time light of the first and the second wavelength, and wherein the optoelectronic devices of the first arrangement are configured to detect the light of the first and second wavelength emitted by the respective optoelectronic device of the second arrangement at the second point of time. Thus, the first arrangement is configured to emit optical data and to detect optical data, and the second arrangement is as well configured to emit and detect optical data. For on optical data communication on each side of the communicating objects it is thus only one arrangement configured to emit and detect optical data necessary and a communication between the communicating objects is realized by sending and emitting data at different points of time. The points of time can also be the same/overlap.

In some embodiments, a first subset of the optoelectronic devices of the first arrangement is configured to emit light of a first and a second wavelength and wherein a respective first subset of the optoelectronic devices of the second arrangement is configured to detect the light of the first and second wavelength emitted by the respective optoelectronic devices of the first subset of the first arrangement, and wherein a second subset of the optoelectronic devices of the second arrangement is configured to emit light of a first and a second wavelength and wherein a respective second subset of the optoelectronic devices of the first arrangement is configured to detect the light of the first and second wavelength emitted by the respective optoelectronic devices of the second subset of the second arrangement. Thus, a first subset of the optoelectronic devices of the first arrangement is configured to emit optical data and a second subset is configured to detect optical data, and vice versa with the second arrangement. For on optical data communication on each side of the communicating objects it is thus only one arrangement configured to subset wise emit and detect optical data necessary and a communication between the communicating objects is realized by splitting the arrangement into emitting and detecting optoelectronic devices.

In a further embodiment, it is provided a method for operating an optoelectronic device according to some embodiments of the proposed principle. The method comprises the steps:
emitting light of a first wavelength by means of the first semiconductor layer stack;
transmitting the light of the first wavelength trough the optical layer, the second semiconductor layer stack and the top contact element;
outcoupling the light of the first wavelength of the optoelectronic device through a light emitting area above the top contact element;
emitting light of a second wavelength by means of the second semiconductor layer stack;
transmitting the light of the second wavelength trough the top contact element but substantially not through the optical layer; and
outcoupling the light of the second wavelength through the light emitting area,
wherein the first wavelength is larger than the second wavelength.

The method can therefore in particular comprise the following steps:
applying a first potential to the bottom contact element;
applying a second potential different to the first potential to the middle contact element; and
applying a third potential different to the first and second potential to the substantially transparent top contact element.

In particular, the optoelectronic device and, in particular, the first and second semiconductor layer stack can be operated by means of two different DC signals with one common potential connected to the middle contact element.

In a further embodiment, it is provided another method for operating an optoelectronic device according to some embodiments of the proposed principle. The method comprises the steps:
transmitting light of a first wavelength incident on a light incident area of the optoelectronic device above the top contact element through the top contact element, the second semiconductor layer stack and the optical layer to the first semiconductor layer stack;
detecting the light of the first wavelength by means of the first semiconductor layer stack;
transmitting light of a second wavelength incident on the light incident area through the top contact element to the second semiconductor layer stack but substantially not through the optical layer; and
detecting the light of the second wavelength by means of the second semiconductor layer stack,
wherein the first wavelength is larger than the second wavelength.

In a further embodiment, it is provided another method for operating an optoelectronic device according to some embodiments of the proposed principle. The method comprises the steps:
emitting light of a first wavelength by means of the first semiconductor layer stack;
transmitting the light of the first wavelength trough the optical layer, the second semiconductor layer stack and the top contact element;
outcoupling the light of the first wavelength of the optoelectronic device through a light emitting area above the top contact element;
transmitting light of a second wavelength incident on a light incident area of the optoelectronic device above the top contact element through the top contact element to the second semiconductor layer stack but substantially not through the optical layer; and
detecting the light of the second wavelength by means of the second semiconductor layer stack,
wherein the first wavelength is larger than the second wavelength.

In a further embodiment, it is provided another method for operating an optoelectronic device according to some embodiments of the proposed principle. The method comprises the steps:
transmitting light of a first wavelength incident on a light incident area of the optoelectronic device above the top contact element through the top contact element, the second semiconductor layer stack and the optical layer to the first semiconductor layer stack;
detecting the light of the first wavelength by means of the first semiconductor layer stack;
emitting light of a second wavelength by means of the second semiconductor layer stack;
transmitting the light of the second wavelength trough the top contact element but substantially not through the optical layer; and
outcoupling the light of the second wavelength through the light emitting area,
wherein the first wavelength is larger than the second wavelength.

In some embodiments, the optoelectronic device is optimized to both emit and detect light, so that at different points of time, the same devices can act as transmitters or receivers.

In some embodiments, the optoelectronic device is optimized to both emit and detect light at the same time. The optoelectronic device can, in particular, be configured to emit light of a first wavelength by means of the first semiconductor layer stack or emit light of a second wavelength by means of the second semiconductor layer stack while detecting light of the other wavelength by means of the other semiconductor layer stack.

In a further embodiment, it is provided a method for operating a system according to some embodiments of the proposed principle. The method comprises the steps:
Emitting light of a first and a second wavelength by means of a first optoelectronic device of the first arrangement;
coupling the light of the first and second wavelength into a first optical fibre;
transmitting the light of the first and second wavelength to a respective first optoelectronic device of the second arrangement;
coupling the light of the first and second wavelength into the first optoelectronic device of the second arrangement; and
detecting the light of the first and second wavelength by means of the first optoelectronic device of the second arrangement.

In a further embodiment it is provided another method for operating a system according to some embodiments of the proposed principle. The method comprises the steps:
emitting light of a first and a second wavelength by means of the first optoelectronic device of the second arrangement;
coupling the light of the first and second wavelength into the first optical fibre; transmitting the light of the first and second wavelength to the first optoelectronic device of the first arrangement;
coupling the light of the first and second wavelength into the first optoelectronic device of the first arrangement; and
detecting the light of the first and second wavelength by means of the first optoelectronic device of the first arrangement.

In a further embodiment it is provided another method for operating a system according to some embodiments of the proposed principle. The method comprises the steps:
emitting light of a first and a second wavelength by means of a second optoelectronic device of the second arrangement;
coupling the light of the first and second wavelength into a second optical fibre;
transmitting the light of the first and second wavelength to a respective second optoelectronic device of the first arrangement;
coupling the light of the first and second wavelength into the second optoelectronic device of the first arrangement; and
detecting the light of the first and second wavelength by means of the second optoelectronic device of the first arrangement.

### BRIEF DESCRIPTION OF THE DRAWINGS

Further embodiments and embodiments in accordance with the proposed principle will become apparent in relation to the various embodiments and examples described in detail in connection with the accompanying drawings in which:

FIG. 1 shows an embodiment of an optoelectronic device in accordance with some embodiments of the proposed principle;

FIG. 2 illustrates a further embodiment of an optoelectronic device in accordance with some embodiments of the proposed principle; and

FIG. 3 shows an embodiment an arrangement with a plurality of optoelectronic devices in accordance with some embodiments of the proposed principle.

### DETAILED DESCRIPTION OF ILLUSTRATIVE EMBODIMENTS

The following embodiments and examples disclose various embodiments and their combinations according to the proposed principle. The embodiments and examples are not always to scale. Likewise, different elements can be displayed enlarged or reduced in size to emphasize individual embodiments. It goes without saying that the individual embodiments of the embodiments and examples shown in the figures can be combined with each other without further ado, without this contradicting the principle according to the invention. Some embodiments show a regular structure or form. It should be noted that in practice slight differences and deviations from the ideal form may occur without, however, contradicting the inventive idea.

In addition, the individual figures and embodiments are not necessarily shown in the correct size, nor do the proportions between individual elements have to be essentially correct. Some embodiments are highlighted by showing them enlarged. However, terms such as “above”, “over”, “below”, “under” “larger”, “smaller” and the like are correctly represented with regard to the elements in the figures. So it is possible to deduce such relations between the elements based on the figures.

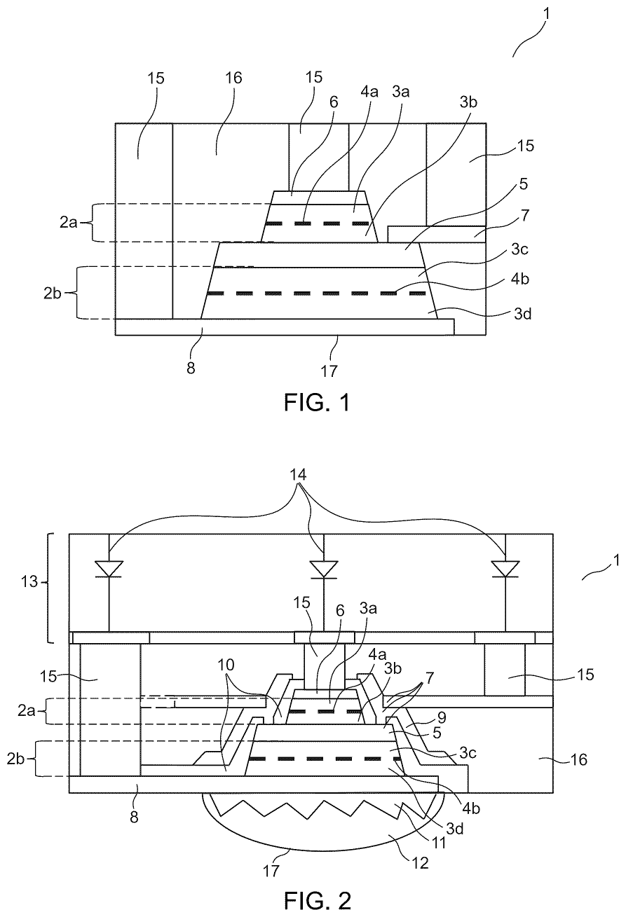

FIG. 1 shows a first embodiment of an optoelectronic device 1 in accordance with some embodiments of the proposed principle. The optoelectronic device 1 comprises a first semiconductor layer stack 2a comprising a first layer 3a, a second layer 3b and a first active region 4a between the first and the second layer 3a, 3b. The first and the second layer 3a, 3b are of different conductivity types. For example, the first layer is an n-doped layer whereas the second layer is a p-doped layer or the other way around. The optoelectronic device 1 further comprises a second semiconductor layer stack 2b arranged on the first semiconductor layer stack 2a comprising a third layer 3c, a fourth layer 3d and a second active region 4b between the third and the fourth layer 3c, 3d. The third and the fourth layer 3c, 3d are of different conductivity types. For example, the third layer is an n-doped layer whereas the fourth layer is a p-doped layer or the other way around. Thus, for example the second and the third layer can be of the same conductivity types or of different conductivity types.

The first active region 4a comprises a smaller bandgap than the second active region 4b such that the first semiconductor layer stack 2a/first active region 4a is configured to emit/detect light of a larger wavelength than the second semiconductor layer stack 2b/second active region 4b.

Between the first semiconductor layer stack 2a and the second semiconductor layer stack 2b an optical layer 5 is arranged. The optical layer 5 comprises a higher transparency for light with energy smaller than the second bandgap, and, in particular, larger to or equal to the first bandgap, than for light with energy equal to or greater than the second bandgap. By this it can be ensured that light with energy smaller than the second bandgap, for example light with a first wavelength being emitted by the first semiconductor layer stack 2a can transmit through the optical layer 5, but light with energy larger than or equal to the second bandgap, for example light with a second wavelength being emitted by the second semiconductor layer stack 2b cannot transmit through the optical layer 5 and will be reflected by optical layer 5.

The optoelectronic device 1 further comprises a bottom contact element 6 electrically contacting the first layer 3a, a middle contact element 7 being in electric contact with the second layer 3b and the third layer 3c and a substantially transparent top contact element 8 electrically contacting the fourth layer 3d. The contact elements 6 and 8 can be semiconductor grown along with one of the two semiconductor stacks 2a and/or 2b, or another material, such as a transparent conductive oxide (TCO) deposited on or bonded to the semiconductor stacks 2a and/or 2b.

The optoelectronic device 1/the first and second semiconductor layer stack 2a, 2b is encapsulated in a filler material 16, for example a polymer filler material. Through the filler material 16 extensions 15 of the bottom, middle and top contact element 6, 7, 8 extend, to provide a contacting of both sides of the optoelectronic device 1. Via these extensions, the optoelectronic device 1 is electrically contactable to operate the optoelectronic device 1 as an emitter and/or detector.

Above the top contact element 8 opposite the semiconductor layer stacks 2a, 2b a light emitting area/light incident area 17 is formed. Through this light emitting area 17 light generated within the semiconductor layer stacks 2a, 2b can be outcoupled from the optoelectronic device 1, or through this light incident area 17, light can be incoupled into the optoelectronic device 1 to be detected by the semiconductor layer stacks 2a, 2b. In the illustrated case the light emitting area/light incident area 17 is formed by the top contact element 8 itself but can also be formed by further structure(s), or element(s) as described later herein.

The semiconductor layer stacks 2a, 2b can comprise a truncated pyramidal shape with angled side surfaces or a truncated conical shape with angled side surfaces. Such angled side surfaces can for example result from a mesa etching process. They can also be pillars or cones with vertical side surfaces. The semiconductor layer stacks 2a, 2b are arranged above each other in steps with the second semiconductor layer stack 2b having a larger cross section as the first semiconductor layer stack 2a and the first semiconductor layer stack 2a being centred with regard to the second semiconductor layer stack 2b. The semiconductor layer stacks can however also comprise similar cross sections centered or not centered to each other.

The middle contact element 7 comprises the optical layer 5 with the optical layer 5 being, for example, a distributed Bragg reflector (DBR). Semiconductor material between the first and the second semiconductor layer stack 2a, 2b comprises substantially transparent current spreader and contact layers for the common middle contact to both semiconductor layer stacks 2a, 2b. This current spreader and contact layers are be combined with the optical layer 5 in form of a DBR. The DBR reflects shorter wavelength light and prevents it from entering the longer wavelength bandgap of the first semiconductor layer stack 2a and transmits the longer wavelength light of or to the first semiconductor layer stack 2a. The DBR is for example monolithically integrated with the first and/or second semiconductor layer stacks 2a, 2b.

The middle contact element 7 further comprises a contact path electrically connecting the at least partially conductive optical layer 5 with the extension 15 through the filler material 15. Via the middle contact element 7 a common potential can be applied to the second and third layer 3b, 3c. The top and the bottom contact element 6, 8 on the other hand can via the extensions 15 through the filler material 16 for example be contacted separately to control the first and the second semiconductor stack 2a, 2b/first and second active region 4a, 4b individually.

FIG. 2 shows another embodiment of an optoelectronic device 1 in accordance with some embodiments of the proposed principle. In addition to aforementioned embodiment, on the bottom side of the optoelectronic device 1 shown in FIG. 1 a carrier substrate 13 is arranged. The carrier substrate 13 comprises a supply circuit 14 being in electric contact with the bottom, middle and top contact element 6, 7, 8 by means of extensions 15. The carrier substrate 13 can for example be a portion of a CMOS wafer and can for example be bonded to the extensions 15 of the bottom, middle and top contact element 6, 7, 8. The carrier substrate 13 can however also be monolithically integrated with the first and second semiconductor layer stack 2a, 2b. Monolithically integrated can in this context for example mean that the carrier substrate 13 and the first and second semiconductor layer stack 2a, 2b are grown on each other by use of for example similar material systems. The carrier substrate 13 comprising the supply circuit 14 can in particular be configured to control the first and the second semiconductor layer stack 2a, 2b in such that the first and the second semiconductor layer stack 2a, 2b can be used as emitters and/or detectors.

In addition to the optoelectronic device shown in FIG. 1 the optoelectronic device 1 comprises an outcoupling/incoupling structure 11 on the top contact element 8 opposite the fourth layer 3d. The outcoupling/incoupling structure 11 can for example be a surface roughening of the top contact element 8 or of a further layer arranged on the top contact element comprising a surface roughening. On the top contact element 8 opposite the fourth layer 3d and on the outcoupling/incoupling structure 11 an optical element 12 is arranged. The optical element 12 can for example be a μ-lens or a photonic structure, to improve an out- and/or incoupling of light from and into the optoelectronic device 1. In addition, by the optical element 12 a directionality of the outcoupled light can be improved. The optical element 12 in this embodiment forms the light emitting area/light incident area 17. The optical element 12 can also be arranged on the top contact element 8 or be part of the top contact element 8, without the presence of the outcoupling/incoupling structure 11. The index of refraction, dimensions and shapes of these two structures 11 and 12 are optimized for improved in and/or out-coupling of light.

The middle contact element 7 further comprises a reflective coating 9 extending alongside surfaces of the first semiconductor layer stack 2a and the second semiconductor layer stack 2b. Between the side surfaces of the first semiconductor layer stack 2a and the second semiconductor layer stack 2b and the reflective coating 9 in addition a dielectric layer 10 is arranged. The dielectric layer 10 serves to protect the semiconductor layer stacks 2a, 2b from a short due to the reflective and electrically conductive coating 9 along the side surfaces. The reflective and electrically conductive coating 9 on the other hand serves as a reflector together with a reflective material layer on the bottom surface of the first layer 3a to guide the light generated within the first and second active region 4a, 4b to the light emitting area 17, or to guide the light incident on the light incident area 17 to the first and second active region 4a, 4b.

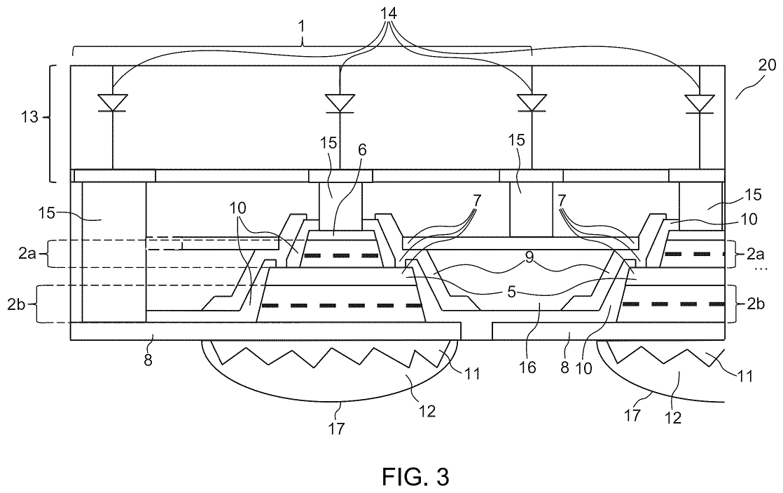

FIG. 3 shows an arrangement 20 in accordance with some embodiments of the proposed principle. The arrangement comprises a plurality of optoelectronic devices 1 in accordance with some embodiments of the proposed principle arranged adjacent to each other on a common carrier substrate 13. In the embodiment shown, exemplarily two optoelectronic devices 1 as shown in FIG. 2 are arranged on a common carrier substrate 13 electrically coupled to each other via the middle contact element 7 sharing a common potential when being applied. By means of the “. . . ” it is to be understood that more than the shown optoelectronic devices 1 can be arranged adjacent to each other. For example, a plurality of optoelectronic devices 1 can be arranged in an array in rows and columns on the common carrier substrate 13. The common carrier substrate 13 can thereby for example be a CMOS wafer providing the necessary supply circuit 14 for operating the optoelectronic devices 1.

An exemplary method for manufacturing such an arrangement 20 can for example comprise the steps:
providing the top contact element 8 on a growth substrate, the top contact element being in particular of a semiconductor material;
providing the second semiconductor layer stack 2b;
providing the optical layer 5 on the second semiconductor layer stack 2b;
providing the first semiconductor layer stack 2a;
providing the bottom contact element 6 on the first semiconductor layer stack 2a, the bottom contact element being for example a semiconductor material or a transparent conductive oxide;
mesa etching to form individual layer stacks in the array;
isolation of the individual layer stacks by etching through the top contact element 8;
providing the dielectric layer 10 on the side surfaces and in-between the first and second semiconductor layer stack 2a and 2b;
opening the dielectric layer 10 at areas to form top and common contacts areas;
providing the electrically conductive and reflective coating 9 on the dielectric layer 10 such that it electrically contacts the optical layer 5 forming a portion of the middle contact element 7;
providing a first portion of the filler material 16;
planarization of the first portion of the filler material 16;
providing the middle contact element 7;
providing a second portion of the filler material 16;
providing extension 15 of the top contact element 8;
providing extension 15 of the middle contact element 7;
providing extension 15 of the bottom contact element 6;
planarization of the second portion of the filler material 16 and extensions 15 to make it suitable for bonding to a carrier substrate 13;
providing the carrier substrate 13 such that it is in electric contact with the bottom, middle and top contact element 6, 7, 8; and
providing the outcoupling/incoupling structure 11 and/or the optical element 12 on the top contact element 8.

Aforementioned steps are however understood to be exemplary and can vary in their order and/or several steps can be dispensed with/are optional.

1.-29. (canceled)

30. A system for optical data communication comprising:
a first arrangement of optoelectronic devices; and
a second arrangement of optoelectronic devices,
wherein the optoelectronic devices of the first arrangement are optically coupled with a respective optoelectronic device of the second arrangement, and
wherein the optoelectronic devices of at least one of the first arrangement or the second arrangement comprise:
a first semiconductor layer stack comprising a first layer, a second layer and a first active region between the first and second layers, wherein the first and second layers are of different conductivity types, and
a second semiconductor layer stack arranged on the first semiconductor layer stack comprising a third layer, a fourth layer and a second active region between the third and fourth layers, wherein the third and fourth layers are of different conductivity types,
an optical layer between the first semiconductor layer stack and the second semiconductor layer stack,
a bottom contact element electrically contacting the first layer,
a middle contact element in electric contact with the second layer and the third layer, and
a substantially transparent top contact element electrically contacting the fourth layer,
wherein the first active region comprises a first bandgap than the second active region comprises a second bandgap,
wherein the first bandgap is smaller than the second bandgap, and
wherein the optical layer comprises a higher transparency for light with energy smaller than the second bandgap.

31. The system according to claim 30,
wherein the optoelectronic devices of the first arrangement are configured to emit light of a first wavelength and a second wavelength, and
wherein the optoelectronic devices of the second arrangement are configured to detect the light of the first wavelength and the second wavelength.

32. The system according to claim 30, wherein the optoelectronic devices of the first arrangement are configured to emit at a first point of time light of a first and a second wavelength, wherein the optoelectronic devices of the second arrangement are configured to detect the light of the first and second wavelength emitted by the respective optoelectronic device of the first arrangement at the first point of time, wherein the optoelectronic devices of the second arrangement are configured to emit at a second point of time light of the first and the second wavelength, and wherein the optoelectronic devices of the first arrangement are configured to detect the light of the first and second wavelength emitted by the respective optoelectronic device of the second arrangement at the second point of time.

33. The system according to claim 30, wherein a first subset of the optoelectronic devices of the first arrangement is configured to emit light of a first and a second wavelength and wherein a respective first subset of the optoelectronic devices of the second arrangement is configured to detect the light of the first and second wavelength emitted by the respective optoelectronic devices of the first subset of the first arrangement, and wherein a second subset of the optoelectronic devices of the second arrangement is configured to emit light of a first and a second wavelength and wherein a respective second subset of the optoelectronic devices of the first arrangement is configured to detect the light of the first and second wavelength emitted by the respective optoelectronic devices of the second subset of the second arrangement.

34. The system according to claim 30, wherein the optical layer of the optoelectronic devices of the first and/or second arrangement is a distributed Bragg reflector.

35. The system according to claim 30, wherein the middle contact element of the optoelectronic devices of the first and/or second arrangement comprises the optical layer.

36. The system according to claim 30, wherein the bottom contact element of the optoelectronic devices of the first and/or second arrangement comprises a reflective material layer covering the first layer opposite the first active region.

37. The system according to claim 30,
wherein the first semiconductor layer stack of the optoelectronic devices of the first and/or second arrangement is configured to emit light of a first wavelength and the second semiconductor layer stack is configured to emit light of a second wavelength, and
wherein the first wavelength is larger than the second wavelength.

38. The system according to claim 30,
wherein the first semiconductor layer stack of the optoelectronic devices of the first and/or second arrangement is configured to detect light of a first wavelength and the second semiconductor layer stack is configured to detect light of a second wavelength, and
wherein the first wavelength is larger than the second wavelength.

39. The system according to claim 30, wherein the optical layer of the optoelectronic devices of the first and/or second arrangement comprises a higher reflectivity for light with energy greater than the second bandgap than for light with energy equal to or smaller than the second bandgap.

40. The system according to claim 30, wherein the middle contact element of the optoelectronic devices of the first and/or second arrangement comprises a reflective coating extending alongside surfaces of the first semiconductor layer stack and/or the second semiconductor layer stack.

41. The system according to claim 40, further comprising a dielectric layer of the optoelectronic devices of the first and/or second arrangement arranged between the side surfaces of the first semiconductor layer stack and/or the second semiconductor layer stack and the reflective coating.

42. The system according to claim 30, wherein the optoelectronic devices of the first and/or second arrangement further comprise an outcoupling structure on the top contact element opposite the fourth layer.

43. The system according to claim 30, wherein the optoelectronic devices of the first and/or second arrangement further comprises an optical element on the top contact element opposite the fourth layer.

44. The system according to claim 30, wherein the optoelectronic devices of the first and/or second arrangement further comprises a carrier substrate, wherein the carrier substrate comprises a supply circuit in electric contact with the bottom, middle and top contact elements.

45. The system according to claim 44, wherein the carrier substrate is bonded to extensions of the bottom, middle and top contact elements.

46. The system according to claim 44, wherein the carrier substrate is monolithically integrated with the first and second semiconductor layer stack.

47. The system according to claim 30,
wherein the bottom contact element of the optoelectronic devices of the first and/or second arrangement is configured to be applied with a first potential,
wherein the middle contact element of the optoelectronic devices of the first and/or second arrangement is configured to be applied with a second potential different to the first potential, and
wherein the substantially transparent top contact element of the optoelectronic devices of the first and/or second arrangement is configured to be applied with a third potential different to the first and second potential.

48. The system according to claim 30, wherein the optoelectronic devices of the first and/or second arrangement are arranged in an array in rows and columns.

49. The system according to claim 48, wherein adjacent optoelectronic devices are connected with a filler material.

50. A method for operating the system according to claim 30, the method comprising:
emitting light of a first wavelength and light of a second wavelength by a first optoelectronic device of the first arrangement;
coupling the light of the first and second wavelength into a first optical fibre;
transmitting the light of the first and second wavelength to a respective first optoelectronic device of the second arrangement;
coupling the light of the first and second wavelengths into a first optoelectronic device of the second arrangement; and
detecting the light of the first and second wavelengths by the first optoelectronic device of the second arrangement.

51. The method according to claim 50, further comprising:
emitting light of the first wavelength and light of the second wavelength by the first optoelectronic device of the second arrangement;
coupling the light of the first and second wavelengths into the first optical fibre;
transmitting the light of the first and second wavelength to the first optoelectronic device of the first arrangement;
coupling the light of the first and second wavelength into the first optoelectronic device of the first arrangement; and
detecting the light of the first and second wavelength by the first optoelectronic device of the first arrangement.

52. The method according to claim 50, further comprising:
emitting light of the first wavelength and light of the second wavelength by a second optoelectronic device of the second arrangement;
coupling the light of the first and second wavelengths into a second optical fibre;
transmitting the light of the first and second wavelengths to a respective second optoelectronic device of the first arrangement;
coupling the light of the first and second wavelengths into the second optoelectronic device of the first arrangement; and
detecting the light of the first and second wavelengths by the second optoelectronic device of the first arrangement.
